(19) United States
(12) Patent Application Publication
(10) Pub. No.: US 2023/0058205 A1
(43) Pub. Date: Feb. 23, 2023

(54) Interband Cascade Infrared Photodetectors and Methods of Use

(71) Applicant: The Board of Regents of the University of Oklahoma, Norman, OK (US)

(72) Inventor: Rui Q. Yang, Norman, OK (US)

(21) Appl. No.: 17/821,039

(22) Filed: Aug. 19, 2022

Related U.S. Application Data
(60) Provisional application No. 63/235,465, filed on Aug. 20, 2021.
(60) Provisional application No. 63/236,045, filed on Aug. 23, 2021.

(51) Int. Cl. H01L 31/111; H01L 31/18

(52) U.S. Cl. CPC H01L 31/111; H01L 31/184; H01L 31/1844; H01L 31/1848; H01L 31/0304

(57) ABSTRACT

An ICIP comprises: a number Nₛ of IC stages, wherein Nₛ is configured to achieve a fundamental limit of the detectivity Dₚₑₐₖ* the ICIP within a range, and wherein each of the IC stages comprises: a hole barrier; an absorber coupled to the hole barrier and comprising a thickness d, wherein d is configured to achieve Dₚₑₐₖ* within the range; and an electron barrier coupled to the absorber. A method of manufacturing an ICIP comprises: determining a number Nₛ of IC stages of the ICIP, wherein Nₛ is configured to achieve a peak detectivity Dₚₑₐₖ* of the ICIP within a range; determining a thickness d of an absorber, wherein d is configured to achieve Dₚₑₐₖ* within the range; obtaining a substrate; forming an electron barrier on the substrate, the absorber having d on the electron barrier, and a hole barrier on the absorber; and repeating the forming Nₛ times.

### CROSS-REFERENCE TO RELATED APPLICATIONS

This claims priority to U.S. Prov. Patent App. No. 63/235,465 filed on Aug. 20, 2021 and U.S. Prov. Patent App. No. 63/236,045 filed on Aug. 23, 2021, both of which are incorporated by reference.

### BACKGROUND

Semiconductor infrared (IR) photodetectors have traditionally used bulk and continuous absorbers where charge carriers are generated by absorbed photons to form photocurrent. The fundamental limit of device performance in terms of detectivity (D*) for these continuous absorber IR photodetectors is reached at the balance between photocurrent and thermal generated noise that is proportional to the absorber thickness. With the development of semiconductor heterostructures and relevant growth technologies such as molecular beam epitaxy (MBE) and metal organic chemical vapor deposition (MOCVD), IR photodetectors with multi-stage discrete absorber architectures emerged. These include quantum well (QW) IR photodetectors (QWIPs), quantum cascade detectors (QCDs), and interband cascade IR photodetectors (ICIPs). QWIPs and corresponding focal plane arrays (FPAs) have been investigated for more than 30 years and are commercially available, while QCDs and ICIPs originating from quantum cascade lasers (QCLs) and interband cascade lasers (ICLs), respectively, have been studied for more than 10 years considering that both QCLs and ICLs have commercial products. However, the fundamental limit of detectivity for these multi-stage discrete absorber IR photodetectors and how it compares with continuous absorber detectors has not been addressed with the exception of current matched ICIPs. Including the effect of the light intensity attenuation inside a detector, the maximum detectivity was obtained and discussed for ICIPs with identical discrete absorbers. However, the electrical gain that was discovered later in ICIPs was not considered, and consequently the obtained value of D* is underestimated. Although the ultimate detectivity in a current-matched ICIPs is somewhat higher than that of the continuous absorber detectors, the current-matching requirement makes them difficult to implement. Multi-stage ICIPs with identical discrete absorbers however can be realized much more easily in practice in addition to having the advantage of a fast response speed. Therefore, it is important to correctly evaluate the ultimate detectivity for identical discrete absorber ICIPs and understand how it can be achieved related to structural parameters compared to those for the conventional continuous absorber detectors. It is to this filling need that the present disclosure is directed.

### BRIEF DESCRIPTION OF THE DRAWINGS

Several embodiments of the present disclosure are hereby illustrated in the appended drawings. It is to be noted however, that the appended drawings only illustrate several typical embodiments and are therefore not intended to be considered limiting the scope of the inventive concepts disclosed herein. The figures are not necessarily to scale and certain features and certain views of the figures may be shown as exaggerated in scale or in schematic in the interest of clarity and conciseness.

FIG. 1 illustrates a schematic layer structure of a multi-stage interband cascade infrared photodetector (ICIP) of the present disclosure.

FIG. 2 shows a schematic band diagram of an ICIP of the present disclosure, in which dashed lines represent type-II hetero-interfaces where electrons recombine with holes from an adjacent stage.

FIG. 3 shows a schematic illustration of an equivalent circuit for a multi-stage IR photodetector.

FIG. 4 shows the collection efficiency as a function of absorber thickness at different values of αL.

FIG. 5 shows a theoretical evaluation of device performance as a function of the αL parameter of absorber material. (a) The optimal absorber thickness for single- and several multi-stage ICIPs. (b) The detectivity of the optimized single- and multi-stage ICIPs employing the absorber thickness from (a) (normalized to the detectivity of single-absorber detector evaluated in the limit of perfect collection) and the corresponding particle conversion efficiency.

FIG. 6 is a flowchart illustrating a method of manufacturing an ICIP of the present disclosure.

### DETAILED DESCRIPTION

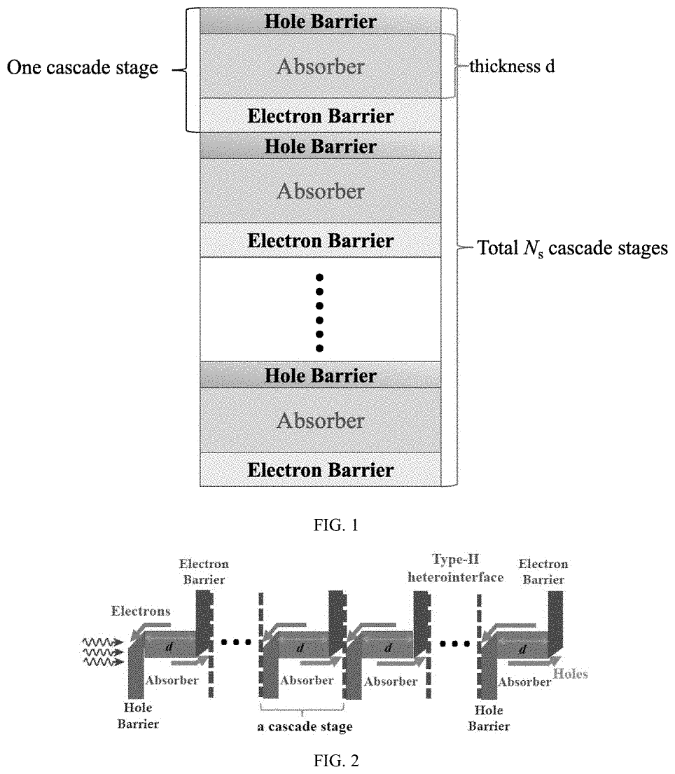

ICIP structures and methods of their use and production are disclosed. The ICIPs are composed of multiple cascade stages with discrete absorbers separated by electron and hole barriers as illustrated in FIG. 1 and FIG. 2, where stages are connected with type-II hetero-interfaces that facilitate interband tunneling. The electron and hole barriers block their namesake carriers. In other words, only holes are allowed in the electron barrier, while only electrons are allowed in the hole barrier. When electron-hole pairs are created by photoexcitation in one stage, the electrons and holes diffuse toward opposite edges of the stage, and then recombine with carriers from adjacent absorbers at the type-II heterointerface between the electron and hole barriers as shown in FIG. 2. Hence, these interfaces together with two contact layers at the two ends of the ICIP structures act as equivalent collection points of photo-generated carriers, and they effectively travel over only a single stage before they recombine. These distinct features in ICIP structures enable the carriers to move fast and reach a collection point that is at most only a single cascade stage distance away, a distance designed to be shorter than the diffusion length. Therefore, the ICIPs can circumvent the diffusion length limitation and suppress noise so that they are beneficial to applications requiring high temperature operation and with high response speed and high detectivities.

Before further describing various embodiments of the apparatus, component parts, and methods of the present disclosure in more detail by way of exemplary description, examples, and results, it is to be understood that the embodiments of the present disclosure are not limited in application to the details of apparatus, component parts, and methods as set forth in the following description. The embodiments of the apparatus, component parts, and methods of the present disclosure are capable of being practiced or carried out in various ways not explicitly described herein. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting unless otherwise indicated as so. Moreover, in the following detailed description, numerous specific details are set forth in order to provide a more thorough understanding of the disclosure. However, it will be apparent to a person having ordinary skill in the art that the embodiments of the present disclosure may be practiced without these specific details. In other instances, features which are well known to persons of ordinary skill in the art have not been described in detail to avoid unnecessary complication of the description. While the apparatus, component parts, and methods of the present disclosure have been described in terms of particular embodiments, it will be apparent to those of skill in the art that variations may be applied to the apparatus, component parts, and/or methods and in the steps or in the sequence of steps of the method described herein without departing from the concept, spirit, and scope of the inventive concepts as described herein. All such similar substitutes and modifications apparent to those having ordinary skill in the art are deemed to be within the spirit and scope of the inventive concepts as disclosed herein.

All patents, published patent applications, and non-patent publications referenced or mentioned in any portion of the present specification are indicative of the level of skill of those skilled in the art to which the present disclosure pertains, and are hereby expressly incorporated by reference in their entirety to the same extent as if the contents of each individual patent or publication was specifically and individually incorporated herein.

Unless otherwise defined herein, scientific and technical terms used in connection with the present disclosure shall have the meanings that are commonly understood by those having ordinary skill in the art. Further, unless otherwise required by context, singular terms shall include pluralities and plural terms shall include the singular.

As utilized in accordance with the methods and compositions of the present disclosure, the following terms and phrases, unless otherwise indicated, shall be understood to have the following meanings: The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or when the alternatives are mutually exclusive, although the disclosure supports a definition that refers to only alternatives and “and/or.” The use of the term “at least one” will be understood to include one as well as any quantity more than one, including but not limited to, 2, 3, 4, 5, 6, 7, 8, 9, 10, 15, 20, 30, 40, 50, 100, or any integer inclusive therein. The phrase “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z.

As used in this specification and claims, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Throughout this application, the terms “about” or “approximately” are used to indicate that a value includes the inherent variation of error for the apparatus, composition, or the methods or the variation that exists among the objects, or study subjects. As used herein the qualifiers “about” or “approximately” are intended to include not only the exact value, amount, degree, orientation, or other qualified characteristic or value, but are intended to include some slight variations due to measuring error, manufacturing tolerances, stress exerted on various parts or components, observer error, wear and tear, and combinations thereof, for example.

The terms “about” or “approximately”, where used herein when referring to a measurable value such as an amount, percentage, temporal duration, and the like, is meant to encompass, for example, variations of ±20% or ±10%, or ±5%, or ±1%, or ±0.1% from the specified value, as such variations are appropriate to perform the disclosed methods and as understood by persons having ordinary skill in the art. As used herein, the term “substantially” means that the subsequently described event or circumstance completely occurs or that the subsequently described event or circumstance occurs to a great extent or degree. For example, the term “substantially” means that the subsequently described event or circumstance occurs at least 90% of the time, or at least 95% of the time, or at least 98% of the time.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

As used herein, all numerical values or ranges include fractions of the values and integers within such ranges and fractions of the integers within such ranges unless the context clearly indicates otherwise. A range is intended to include any sub-range therein, although that sub-range may not be explicitly designated herein. Thus, to illustrate, reference to a numerical range, such as 1-10 includes 1, 2, 3, 4, 5, 6, 7, 8, 9, 10, as well as 1.1, 1.2, 1.3, 1.4, 1.5, etc., and so forth. Reference to a range of 2-125 therefore includes 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, and 125, as well as sub-ranges within the greater range, e.g., for 2-125, sub-ranges include but are not limited to 2-50, 5-50, 10-60, 5-45, 15-60, 10-40, 15-30, 2-85, 5-85, 20-75, 5-70, 10-70, 28-70, 14-56, 2-100, 5-100, 10-100, 5-90, 15-100, 10-75, 5-40, 2-105, 5-105, 100-95, 4-78, 15-65, 18-88, and 12-56. Reference to a range of 1-50 therefore includes 1, 2, 3, 4, 5, 6, 7, 8, 9, 10, 11, 12, 13, 14, 15, 16, 17, 18, 19, 20, etc., up to and including 50, as well as 1.1, 1.2, 1.3, 1.4, 1.5, etc., 2.1, 2.2, 2.3, 2.4, 2.5, etc., and so forth. Reference to a series of ranges includes ranges which combine the values of the boundaries of different ranges within the series. Thus, to illustrate reference to a series of ranges, for example, a range of 1-1,000 includes, for example, 1-10, 10-20, 20-30, 30-40, 40-50, 50-60, 60-75, 75-100, 100-150, 150-200, 200-250, 250-300, 300-400, 400-500, 500-750, 750-1,000, and includes ranges of 1-20, 10-50, 50-100, 100-500, and 500-1,000. The range 100 units to 2000 units therefore refers to and includes all values or ranges of values of the units, and fractions of the values of the units and integers within said range, including for example, but not limited to 100 units to 1000 units, 100 units to 500 units, 200 units to 1000 units, 300 units to 1500 units, 400 units to 2000 units, 500 units to 2000 units, 500 units to 1000 units, 250 units to 1750 units, 250 units to 1200 units, 750 units to 2000 units, 150 units to 1500 units, 100 units to 1250 units, and 800 units to 1200 units. Any two values within the range of about 100 units to about 2000 units therefore can be used to set the lower and upper boundaries of a range in accordance with the embodiments of the present disclosure. More particularly, a range of 10-12 units includes, for example, 10, 10.1, 10.2, 10.3, 10.4, 10.5, 10.6, 10.7, 10.8, 10.9, 11.0, 11.1, 11.2, 11.3, 11.4, 11.5, 11.6, 11.7, 11.8, 11.9, and 12.0, and all values or ranges of values of the units, and fractions of the values of the units and integers within said range, and ranges which combine the values of the boundaries of different ranges within the series, e.g., 10.1 to 11.5. Reference to an integer with more (greater) or less than includes any number greater or less than the reference number, respectively. Thus, for example, reference to less than 100 includes 99, 98, 97, etc. all the way down to the number one (1); and less than 10 includes 9, 8, 7, etc. all the way down to the number one (1).

The present disclosure will now be discussed in terms of several specific, non-limiting, examples and embodiments. The examples described below, which include particular embodiments, will serve to illustrate the practice of the present disclosure, it being understood that the particulars shown are by way of example and for purposes of illustrative discussion of particular embodiments and are presented in the cause of providing what is believed to be a useful and readily understood description of procedures as well as of the principles and conceptual aspects of the present disclosure.

The following abbreviations apply:
AlGaInAsN: aluminum gallium indium arsenic nitride
AlGaInAsP: aluminum gallium indium arsenic phosphide
AlInAsP: aluminum indium arsenic phosphide
AlSb: aluminum antimonide
AlSbAs: aluminum antimony arsenide
InGaAsSb: indium gallium arsenic antimonide
FPA: focal plane array
GaInSb: gallium indium antimonide
GaSb: gallium antimonide
GHz: gigahertz
ICL: interband cascade laser
InAs: indium arsenide
InAsP: indium arsenic phosphide
InAsSb: indium arsenic antimonide
ICIP: interband cascade IR photodetectors
IR: infrared
K: Kelvin
kHz: kilohertz
MBE: molecular beam epitaxy
MOCVD: metal organic chemical vapor deposition
QCD: quantum cascade detector
QCL: quantum cascade laser
QW: quantum well
QWIP: quantum well IR photodetector
SL: superlattice
T: temperature.

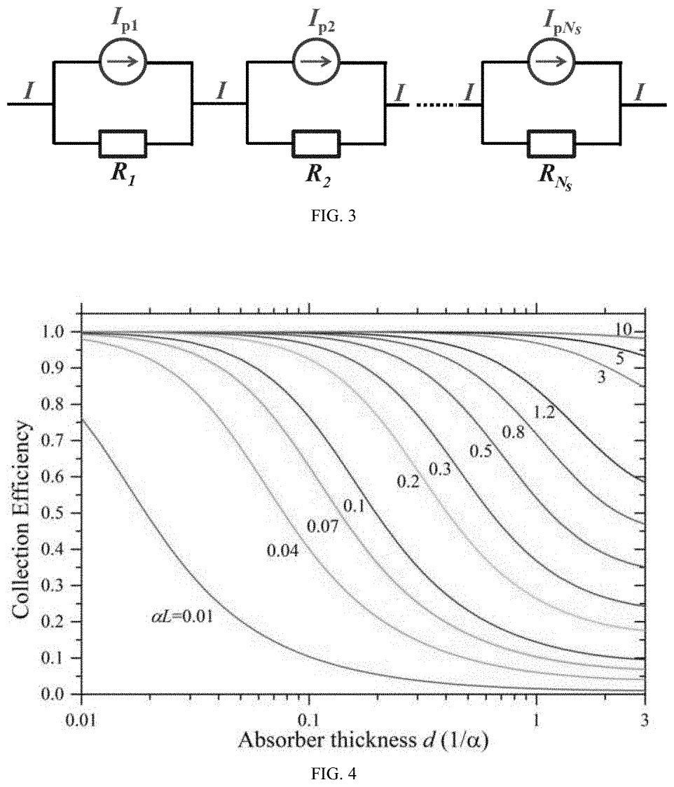

A multi-stage IR photodetector can be represented by a simple equivalent circuit as shown in FIG. 3, where every individual stage comprises a current source with photocurrent Iₚₘ (m=1, 2, . . . , Nₛ, where Nₛ is the number of cascade stages) and a parallel resistance Rₘ. The photocurrent is not necessarily the same in different stages for various factors such as nonuniformities of electrical field and carrier distributions, and light intensity attenuation due to absorption of photons in preceding stages. The later factor was neglected in the research of QWIPs but is the main aspect addressed in this work. The mismatch of photocurrent between stages will generate a change in electrical potential ΔVₘ across every stage and self-adjusting Vₘ so that:

Σₘ₌₁^{N}^{ₛ}ΔVₘ=0, (1)

because the generation of ΔVₘ does not modify the external bias voltage on the detector. Consequently, an extra current ΔIₘ is produced through Rₘ due to ΔVₘ. Therefore, the total current I across each stage has three terms, Iₚₘ, ΔIₘ, and the dark current I_{d}, and should be the same because all individual stages are connected in series.

With a weak light incident on the ICIP, photocurrent in an individual stage Iₚₘ is small and consequently the electrical potential ΔVₘ is small. Thus, the current ΔIₘ has a linear relationship with ΔVₘ. Then the total current I in the circuit can be written as:

$$I = {I}_{pm} + \frac{{ΔV}_{m}}{{R}_{m}} + {I}_{d} . \qquad ( 2 )$$

### Rewriting Eq. (2) as:

IRₘ=IₚₘRₘ+ΔVₘ+I_{d}Rₘ, (3)

then adding Eq. (3) over all different stages and using Eq. (1), provides:

IΣₘ₌₁^{N}^{ₛ}Rₘ=Σₘ₌₁^{N}^{ₛ}IₚₘRₘ+I_{d}Σₘ₌₁^{N}^{ₛ}Rₘ. (4)

Rearranging Eq. (4), the total current can be obtained as:

$$I = \frac{{\sum }_{m = 1}^{{N}_{s}} {I}_{pm} {R}_{m}}{{\sum }_{m = 1}^{{N}_{s}} {R}_{m}} + {I}_{d} . \qquad ( 5 a )$$

The first term in Eq. 5(a) is the signal current Iₛ, valid with a finite bias voltage. Considering ICIPs with identical discrete absorbers, resistance in every stage is the same and the signal current is simplified as:

$${I}_{s} = \frac{{\sum }_{m = 1}^{{N}_{s}} {I}_{pm}}{{N}_{s}} , \qquad ( 5 b )$$

which means that the signal current is determined by the average value of photocurrent over all the stages, rather than the lowest photocurrent I_{pNs} in the last stage assumed previously. This suggests an electrical gain arising from the difference between Iₛ and I_{pNs} due to photocurrent mismatch between stages, which is consistent with the result obtained from an alternative method and supported by the experimental findings. Consequently, considering light attenuation by absorption in preceding stages, quantum efficiency (QE) η is given by:

$$η = \frac{{η}_{1}}{{N}_{s}} {\sum }_{m = 1}^{{N}_{s}} {e}^{- α ( m - 1 ) d} = \frac{{η}_{a}}{{N}_{s}} {η}_{c} = \frac{{η}_{part}}{{N}_{s}} . \qquad ( 6 )$$

where ηₐ=[1−exp(−αNₛd)] is absorption efficiency, η_{c}=η₁/ ηₐᵢ is the collection efficiency measuring how efficient photogenerated carriers are collected in an individual absorber with absorption coefficient α and a thickness of d, and ηₐᵢ=[1−exp(−αd)] is the absorption efficiency for an individual absorber. ηₚₐᵣₜ is given by:

ηₚₐᵣₜ=η_{c}ηₐ (7)

and is the particle conversion efficiency that is defined as the sum of percentage of collected carriers in every stage to the incident photons. Here, η₁ is the QE for the first absorber, which is given by:

$${η}_{1} = \frac{α L}{1 - {( α L )}^{2}} \times [ tanh ( d / L ) + \frac{α {Le}^{- α d}}{cosh ( d / L )} - α L ] \qquad ( 8 )$$

for diffusion determined carrier transport with a finite diffusion length L.

Eq. (6) has a clear physical implication: with Nₛ identical discrete absorbers, an ICIP requires Nₛ photons to create a single electron in the external circuit, which exactly reverses multiple photon generation per electron in an ICL. This result should also be applicable to other types of multi-stage photodetectors such as QWIPs and QCDs where η₁ may not have the same form as Eq. (8) with different carrier transport mechanisms. This is because QWIPs and QCDs are also subject to the effect of light attenuation inside their absorbers, especially with many stages, despite their distinctive transition mechanism from ICIPs. Similarly, the electric potential across each stage in QWIPs and QCDs will self-adjust to ensure that the current continuity and electrical gain will supplement the photocurrent in the optically deeper stages. Also, it is worth pointing out that although the relation η=ηₚₐᵣₜ/Nₛ in Eq. (6) looks like what obtained previously for QWIPs where the light attenuation was not considered, the derivation with modified terms is different from what were described for QWIPs.

At zero-bias, the thermal-noise-limited detectivity (D*) of a detector is proportional to the external QE η and the square root of the product of resistance R₀ and area A. For an ICIP where individual absorbers are connected in series through interband tunneling with type-II heterostructures, its resistance is the sum of the individual absorber resistances Rₘ and is given by:

$${R}_{0} A = {\sum }_{m = 1}^{{N}_{s}} {R}_{m} A = \frac{{k}_{b} T}{{e}^{2} {g}_{th} L} \frac{{N}_{s}}{tanh ( d / L )} , \qquad ( 9 )$$

where e is the electron charge, k_{b} is the Boltzmann constant, gₜₕ is the thermal generation rate, and T is the device temperature. Hence, the thermal-noise-limited detectivity for multi-stage ICIPs with identical absorbers can be expressed as:

$${D}^{*} = \frac{λ e}{hc} η \sqrt{\frac{{R}_{0} A}{4 {k}_{b} T}} = \frac{λ}{hc} \frac{{η}_{c}}{\sqrt{4 {g}_{th} L}} \frac{1 - {e}^{- α {N}_{s} d}}{{N}_{s}} \sqrt{\frac{{N}_{s}}{tanh ( d / L )}} = \frac{λ}{hc} \frac{{η}_{part}}{\sqrt{4 {g}_{th} L}} \sqrt{\frac{1}{{N}_{s} tanh ( d / L )}} \qquad ( 10 )$$

where h is Planck's constant, c is the speed of light in a vacuum, and λ is the wavelength of an incident light. As can be seen from Eq. (10), the increase of absorber thickness d could increase particle conversion efficiency and consequently enhance the D*, but it decreases the resistance with more noise as shown by the square root term, which reduces D*. Hence, a maximum D* is achieved at an optimal thickness d similar to what was discussed for the single-absorber detector. To illustrate how this can be achieved for maximizing the detectivity, we consider the case of an infinite diffusion length. This is instructive as it highlights the improvement that is possible in a multiple-stage device through an increase of the collection efficiency and particle conversion efficiency. In the limit of L→∞η_{c}=1, one can simplify Eq. (10) as:

$${D}^{*} = \frac{λ}{hc} \frac{1 - {e}^{- α {N}_{s} d}}{\sqrt{4 {g}_{th}}} \sqrt{\frac{1}{{N}_{s} d}} . \qquad ( 11 )$$

Setting Nₛd=dₜₒₜₐₗ, one can see Eq. (11) is the same as the expression of D* for the conventional single-stage detector with an absorber thickness of dₜₒₜₐₗ. Therefore, ICIPs with identical discrete absorbers have the same ultimate detectivity:

$${D}_{peak}^{*} = ( 0.319 ) \frac{λ}{hc} \sqrt{\frac{α}{{g}_{th}}} \qquad ( 12 a )$$

as the single-stage value, independent of the number of cascade stages, which is reached when:

Nₛd=dₜₒₜₐₗ=1.26/α. (12b)

This can be obtained by setting ∂D*/∂dₜₒₜₐₗ=0. The result represented by Eqs. (12a-12b) indicates that the reduction of QE in a multi-stage ICIP as shown in Eq. (6) is exactly balanced by the increase of device resistance (or suppression of noise) in the limit of perfect collection (L→∞) as implied in Eq. (11).

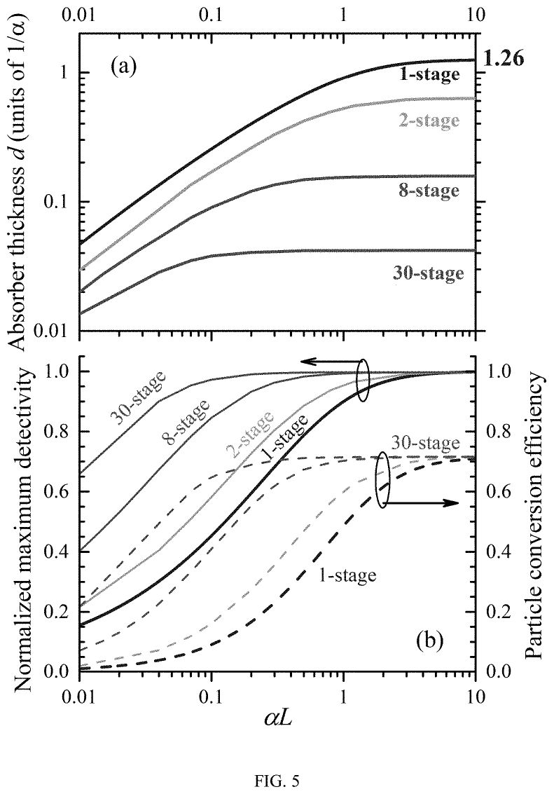

In real devices with a finite L, the collection efficiency η_{c} is less than 100% and decreases with increasing absorber thickness for diffusion dominated carrier transport as shown in FIG. 4. Particularly, when αL is small, which is usually true in narrow bandgap semiconductors for long wavelength IR detectors, η_{c} drops significantly with increasing d. From Eq. (10), D* will decrease with the reduction of η_{c}. Consequently, the optimal absorber thickness needs to be reduced to maximize D* as shown in FIG. 5(a) where the optimal d is calculated numerically and plotted as a function of αL. Thus, the detectivity reduces with the decrease of αL. This is significant for the conventional single-stage detector as shown in FIG. 5(b). In multi-stage ICIPs, the reduction of D* is small and can be substantially mitigated with more stages. This is because individual absorbers can be made thinner than the diffusion length so the collection and particle conversion efficiencies can still maintain high values. This is demonstrated in the calculated results shown in FIG. 5(b) for three ICIPs with different numbers of stages. For example for the ICIP with 30 identical discrete absorbers, the ultimate value of D* is nearly a constant from the highest number until αL=0.1 with the particle efficiency maintaining approximately the optimal value of 71%. Instead of the conventional external QE, the particle conversion efficiency ηₚₐᵣₜ is a more appropriate figure of merit for ICIPs as illustrated in Eqs. (7) and (10) and is universally higher in ICIPs than that in the conventional single-stage detector when the diffusion length is finite.

Compared to the results with strict conditions for current matched ICIPs, these results for ICIPs with identical discrete absorbers have more significance to improve photodetector device performance in practice. Without requirements of current-matching, multi-stage ICIPs with identical discrete absorbers will be robust and durable against structural variations, and yet can still have a detectivity approaching the ultimate limit as illustrated herein. In actual circumstances, even when the individual absorbers are not exactly identical, the signal current would substantially be an average of photocurrent over all individual stages so that the detectivity can be very close to the fundamental limit of Johnson-noise-lmited detetivity. Hence, the ICIP configuration would be especially beneficial to long-wave (LW) and very LW IR photodetectors based on absorber materials such as Ga-free InAs/InAsSb superlattices (SLs) where a small absorption coefficient and a short diffusion length are typical concerns. Also, ICIPs with identical discrete absorbers will be more advantageous for simultaneously high sensitivity and high-speed operation as demonstrated already with high-frequency operation from 1.3 to 10 GHz. Furthermore, the results and underlying physics discussed here should be applicable to photovoltaic QWIPs and QCDs with periodic absorbing regions made of either QWs or SLs. In addition to what was discussed earlier related to Eq. (6) on the relation between η and ηₚₐᵣₜ, QWIPs and QCDs may have an optimal number of stages (or QWs for absorption) for a maximum detectivity, similar to what is implied in Eq. (12b). This is because they are also subject to the effect of light attenuation correlated with absorption inside the device. The effect of light attenuation inside QWIPs and QCDs was neglected in the past. This however should have a substantial impact on device performance when there are many QWs for absorption. These results and the relevant discussion on the underlying physics will further improve the understanding of multi-stage IR photodetectors for a range of applications.

The ICIP may implement additional embodiments. For instance, Nₛ may be configured to achieve Dₚₑₐₖ* within a range. d may be configured to achieve Dₚₑₐₖ* within the range. Nₛ may be chosen not exceeding 1.26/(αd) as suggested by Eq. (12b). The range may be ±50%. d may be based on a product of an absorption coefficient α of the absorber and a finite diffusion length L of the absorber. d may be about 0.035/α when Nₛ=30 and αL=0.07, about 0.12/α when Nₛ=8 and αL=0.2, about 0.5/α when Nₛ=2 and αL=0.8. The αL product depends on absorber material and device operating temperature, which can be obtained through measurements of the semiconductor materials that are used. The hole barrier may comprise a first band gap, the absorber may comprise a second band gap that is less than the first band gap, and the electron barrier may comprise a third band gap that is greater than the second band gap. The absorber may be configured to absorb photons. FIG. 2 shows a schematic band diagram of an ICIP of the present disclosure, which shows the flow of holes and electrons through the stages of the ICIP.

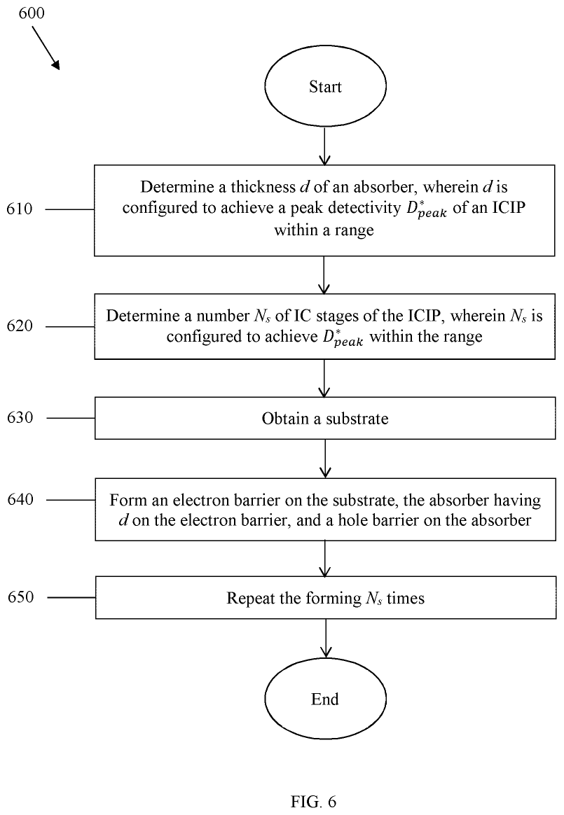

FIG. 6 is a flowchart illustrating a method 600 of manufacturing an ICIP. At step 610, a thickness d of an absorber is determined. d is configured to achieve Dₚₑₐₖ* within the range. At step 620, a number Nₛ of IC stages of the ICIP is determined. Nₛ is configured to achieve a peak detectivity Dₚₑₐₖ* of the ICIP within a range. For instance, d is as shown with a given Nₛ and achievable D* in FIG. 5. At step 630, a substrate is shown. The substrate may be chosen from a group including but not limited to GaSb, InAs, GaAs and Si. At step 640, an electron barrier is formed on the substrate, the absorber having d is formed on the electron barrier, and a hole barrier is formed on the absorber. For instance, the electron barrier, the absorber, and the hole barrier are as shown in FIG. 1. At step 650, the forming is repeated Nₛ times. The construction of one cascade stage can also be made in reverse order, i.e. first a hole barrier, then the absorber having d and an electron barrier on the absorber.

Nₛ may be in a range of 2 to about 125. For example, Nₛ may be 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, or 125.

In certain embodiments, the thickness of the absorber of an IC stage may be in a range of 5 nm to 3000 nm, depending on the absorption coefficient and diffusion length. Exemplary ranges of absorber thickness include but are not limited to, 5 nm to 1000 nm, 5 nm to 2000 nm, 10 nm to 500 nm, 10 nm to 400 nm, 10 nm to 300 nm, 10 nm to 200 nm, 10 nm to 100 nm, 5 nm to 500 nm, 5 nm to 250 nm, 5 nm to 200 nm, 5 nm to 100 nm, 5 nm to 50 nm, 10 nm to 50 nm, 7 nm to 100 nm, 7 nm to 50 nm, and 7 nm to 25 nm. Thicknesses of the absorbers of the multiple IC stages in an ICIP may be substantially equal, or they may vary from one stage to another.

In certain embodiments, the thickness of the electron barrier of an IC stage may be in a range of 7 nm to 120 nm. Exemplary ranges of absorber thickness include but are not limited to, 7 nm to 115 nm, 7 nm to 110 nm, 7 nm to 100 nm, 7 nm to 75 nm, 7 nm to 65 nm, 7 nm to 50 nm, 7 nm to 40 nm, 7 nm to 30 nm, 7 nm to 25 nm, 7 nm to 20 nm, 7 nm to 15 nm, 8 nm to 115 nm, 8 nm to 110 nm, 8 nm to 100 nm, 8 nm to 75 nm, 8 nm to 65 nm, 8 nm to 50 nm, 8 nm to 40 nm, 8 nm to 30 nm, 8 nm to 25 nm, 8 nm to 20 nm, 8 nm to 15 nm, 9 nm to 115 nm, 9 nm to 110 nm, 9 nm to 100 nm, 9 nm to 75 nm, 9 nm to 65 nm, 9 nm to 50 nm, 9 nm to 40 nm, 9 nm to 30 nm, 9 nm to 25 nm, 9 nm to 20 nm, 9 nm to 15 nm, 10 nm to 115 nm, 10 nm to 110 nm, 10 nm to 100 nm, 10 nm to 75 nm, 10 nm to 65 nm, 10 nm to 50 nm, 10 nm to 40 nm, 10 nm to 30 nm, 10 nm to 25 nm, 10 nm to 20 nm, and 10 nm to 15 nm. Thicknesses of the electron barriers of the multiple IC stages in an ICIP may be substantially equal, or they may vary from one stage to another.

In certain embodiments, the thickness of the hole barrier of an IC stage may be in a range of 9 nm to 150 nm. Exemplary ranges of absorber thickness include but are not limited to, 9 nm to 150 nm, 9 nm to 145 nm, 9 nm to 140 nm, 9 nm to 135 nm, 9 nm to 130 nm, 9 nm to 125 nm, 9 nm to 120 nm, 9 nm to 115 nm, 9 nm to 110 nm, 9 nm to 100 nm, 9 nm to 90 nm, 9 nm to 80 nm, 9 nm to 75 nm, 9 nm to 65 nm, 9 nm to 50 nm, 9 nm to 40 nm, 9 nm to 30 nm, 9 nm to 25 nm, 9 nm to 20 nm, 9 nm to 15 nm, 10 nm to 150 nm, 10 nm to 145 nm, 10 nm to 140 nm, 10 nm to 135 nm, 10 nm to 130 nm, 10 nm to 125 nm, 10 nm to 120 nm, 10 nm to 115 nm, 10 nm to 110 nm, 10 nm to 100 nm, 10 nm to 90 nm, 10 nm to 80 nm, 10 nm to 75 nm, 10 nm to 65 nm, 10 nm to 50 nm, 10 nm to 40 nm, 10 nm to 30 nm, 10 nm to 25 nm, 10 nm to 20 nm, and 10 nm to 15 nm. Thicknesses of the hole barriers of the multiple IC stages in an ICIP may be substantially equal, or they may vary from one stage to another.

The method 600 may implement additional embodiments. For instance, the range may be ±50%. d may be based on a product of an absorption coefficient α of the absorber and a finite diffusion length L of the absorber. d may be about 0.035/α when Nₛ=30 and αL=0.07, about 0.12/α when Nₛ=8 and αL=0.2, about 0.5/α when Nₛ=2 and αL=0.8. An ICIP may be prepared by a process comprising the steps of the method 600.

While several embodiments have been provided in the present disclosure, it may be understood that the disclosed apparatus, systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, apparatus and methods described and illustrated in the various embodiments as discrete or separate may be combined or integrated with other systems, components, techniques, or methods without departing from the scope of the present disclosure. Other items shown or discussed as coupled may be directly coupled or may be indirectly coupled or communicating through some interface, device, or intermediate component whether electrically, mechanically, or otherwise. Other examples of changes, substitutions, and alterations are ascertainable by one skilled in the art and may be made without departing from the spirit and scope disclosed herein.

What is claimed is:

1. An interband cascade infrared photodetector (ICIP) comprising:
a number Nₛ of interband cascade (IC) stages, wherein Nₛ is greater than one and is configured to achieve a peak detectivity Dₚₑₐₖ* the ICIP within a range, and wherein each of the IC stages comprises:
a hole barrier;
an absorber coupled to the hole barrier and comprising a thickness d, wherein d is configured to achieve Dₚₑₐₖ* within the range, and wherein the absorber is configured to absorb photons; and
an electron barrier coupled to the absorber, wherein the hole barrier comprises a first band gap, the absorber comprises a second band gap that is less than the first band gap, and the electron barrier comprises a third band gap that is greater than the second band gap.

2. The ICIP of claim 1, wherein the range is ±50%.

3. The ICIP of claim 1, wherein d is based on a product of an absorption coefficient α of the absorber and a finite diffusion length L of the absorber.

4. The ICIP of claim 3, wherein d is about 0.035/α when Nₛ=30 and αL=0.07.

5. The ICIP of claim 3, wherein d is about 0.12/α when Nₛ=8 and αL=b 0.2.

6. The ICIP of claim 3, wherein d is about 0.5/α when Nₛ=2 and αL=0.8.

7. The ICIP of claim 1, wherein the absorber comprises a semiconductor layer selected from the group consisting of InAs, InAsSb, InGaAs, InGaAsSb, GaSb, GaInSb, AlGaSb, AlGaInSb, AlGaInAsN, GaAs, AlSb, AlAs, AlInSb, AlSbAs, AlGaSbAs, and AlInGaSbAs.

8. The ICIP of claim 1, wherein the hole barrier comprises a semiconductor layer selected from the group consisting of InAs, InAsSb, InGaAs, InGaAsSb, GaSb, GaInSb, AlGaSb, AlGaInSb, AlGaInAsP, AlInAsP, GaAs, AlSb, AlAs, AlInSb, AlSbAs, AlGaSbAs, and AlInGaSbAs.

9. The ICIP of claim 1, wherein the electron barrier comprises a semiconductor layer selected from the group consisting of InAs, InAsSb, InGaAs, InGaAsSb, GaSb, GaInSb, AlGaSb, AlGaInSb, AlGaInAsP, AlInAsP, GaAs, AlSb, AlAs, AlInSb, AlSbAs, AlGaSbAs, and AlInGaSbAs.

10. The ICIP of claim 1, further comprising a substrate upon which the IC stages are disposed, the substrate selected from the group consisting of InAs, InP, GaAs, GaSb, and Si.

11. The ICIP of claim 1, wherein the thicknesses d of the absorbers of the Nₛ IC stages are substantially equal.

12. The ICIP of claim 1, wherein the thicknesses d of the absorbers of the Nₛ IC stages are not all equal.

13. A method of manufacturing an interband cascade infrared photodetector (ICIP) and comprising:
(a) determining a number Nₛ of interband cascade (IC) stages of the ICIP, wherein Nₛ is greater than one and configured to achieve a peak detectivity Dₚₑₐₖ* of the ICIP within a range;
(b) determining a thickness d of an absorber, wherein d is configured to achieve Dₚₑₐₖ* within the range, wherein the absorber is configured to absorb photons; and
(c) forming the Nₛ IC stages on a substrate by forming a hole barrier on the substrate, forming the absorber on the hole barrier, and forming an electron barrier on the absorber, or
(d) forming the Nₛ IC stages on a substrate by forming an electron barrier on the substrate, forming the absorber on the electron barrier, and forming a hole barrier on the absorber,
wherein the hole barrier comprises a first band gap, the absorber comprises a second band gap that is less than the first band gap, and the electron barrier comprises a third band gap that is greater than the second band gap; and
repeating the step (c) or the step (d) Nₛ times.

14. The method of claim 13, wherein the range is ±50%.

15. The method of claim 13, wherein d is based on a product of an absorption coefficient α of the absorber and a finite diffusion length L of the absorber.

16. The method of claim 15, wherein d is about 0.035/α when Nₛ=30 and αL=0.07, about 0.12/α when Nₛ=8 and αL=0.2, about 0.5/α when Nₛ=2 and αL=0.8.

17. An interband cascade infrared photodetector (ICIP) prepared by a process comprising the steps of:
(a) determining a number Nₛ of interband cascade (IC) stages of the ICIP, wherein Nₛ is greater than one and configured to achieve a peak detectivity Dₚₑₐₖ* of the ICIP within a range;
(b) determining a thickness d of an absorber, wherein d is configured to achieve Dₚₑₐₖ* within the range, wherein the absorber is configured to absorb photons; and
(c) forming the Nₛ IC stages on a substrate by forming a hole barrier on the substrate, forming the absorber on the hole barrier, and forming an electron barrier on the absorber, or
(d) forming the Nₛ IC stages on a substrate by forming an electron barrier on the substrate, forming the absorber on the electron barrier, and forming a hole barrier on the absorber,
wherein the hole barrier comprises a first band gap, the absorber comprises a second band gap that is less than the first band gap, and the electron barrier comprises a third band gap that is greater than the second band gap; and
repeating the step (c) or the step (d) Nₛ times.

18. The ICIP of claim 17, wherein d is based on a product of an absorption coefficient α of the absorber and a finite diffusion length L of the absorber.
